(19) United States
(12) Patent Application Publication
(10) Pub. No.: US 2008/0007535 A1
(43) Pub. Date: Jan. 10, 2008

(54) Touch panel having only two voltage input terminals

(75) Inventor: Zi-Sheng Li, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/725,959

(22) Filed: Mar. 19, 2007

(30) Foreign Application Priority Data
Mar. 17, 2006 (TW) 95109290

(51) Int. Cl. G06F 3/041; G02F 1/133; H03K 17/96

(52) U.S. Cl. 345/173; 327/517; 349/23

(57) ABSTRACT

An exemplary touch panel (2) includes a first input layer (21) having an output terminal, and a second input layer (22) parallel to the first input layer. The second input layer includes a first electrical set, a second electrical set, a mesh circuit, and a switch circuit. The first electrical set includes a first electrical node (241), a second electrical node (242), a third electrical node (243), and a fourth electrical node (244), the first, second, third, and fourth electrical nodes respectively located at four vertexes of an imaginary rectangle on the second input layer. The mesh circuit having a plurality of resistors (238) connected between the four electrical nodes. The second electrical set includes a first input terminal and a second input terminal. The switch circuit electrically connected between the first electrical set and the second electrical set. The configuration of the touch panel (2) is simplified.

### FIELD OF THE INVENTION

The present invention relates to a touch panel having only two voltage input terminals, the touch panel typically being used in a liquid crystal display (LCD).

### GENERAL BACKGROUND

An LCD device has the advantages of portability, low power consumption, and low radiation, and has been widely used in various portable information products such as notebooks, personal digital assistants (PDAs), video cameras and the like. An LCD normally includes an LCD panel. When the LCD panel is used in a product such as a PDA, it is desirable to omit a keyboard or certain special function buttons in order to save on space. Therefore it is common for a touch panel to be fixed on a surface of the LCD panel. When a user presses the touch panel at a desired location on the touch panel with his/her finger or with a stylus, an electronic signal is generated, and the PDA can perform a predetermined function according to the generated signal.

FIG. 5 is a schematic, exploded, abbreviated isometric view of a typical touch panel, showing circuitry thereof. The touch panel 1 includes a first input layer 11, and a second input layer 12 that is parallel to the first input layer 11. The first input layer 11 and the second input layer 12 are spaced apart from each other.

The first input layer 11 includes an output terminal 111. The second input layer 12 includes a first electrical node 141, a second electrical node 142, a third electrical node 143, and a fourth electrical node 144, which are respectively located at four vertexes of an imaginary square defined on the second input layer 12. The second input layer 12 also includes a first input terminal 131 connected to the first electrical node 141, a second input terminal 132 connected to the second electrical node 142, a third input terminal 133 connected to the third electrical node 143, and a fourth input terminal 134 connected to the fourth electrical node 144. The second input layer 12 further includes a mesh circuit 13 connected with the four electrical nodes 141, 142, 143, 144.

The mesh circuit 13 includes a plurality of connecting nodes 135 (only one labeled) and a plurality of resistors 136 (only one labeled). In general, each resistor 136 is connected between two corresponding adjacent connecting nodes 135. However, certain of the resistors 136 are connected between a respective one of the first, second, third, and fourth electrical nodes 141, 142, 143, 144 and a corresponding adjacent connecting node 135. Resistances of the resistors 136 are equal to each other. Distances between two adjacent connecting nodes 135 (and between any one of the first, second, third, and fourth electrical nodes 141, 142, 143, 144 and the corresponding adjacent connecting node 135) are equal to each other.

In order to conveniently describe operation of the touch panel 1, each of the first input layer 11 and the second input layer 12 is defined to include Cartesian axes (i.e. an X-axis and a Y-axis). Referring also to FIGS. 6, 7 and 8, the operation of the touch panel 1 is generally as follows:

When a user's finger (or a stylus) touches the first input layer 11, a touch point 112 on the first input layer 11 is electrically connected to a corresponding connecting node 135a of the mesh circuit 13 of the second input layer 12. A period of time during which the touch point 112 is connected to the corresponding connecting node 137 is divided into a first period “t₁” and a second period “t₂”. The first period “t₁” can be a first half of said period of time. The second period “t₂” can be a second half of said period of time.

In the first period “t₁”, a high level voltage is provided to the first input terminal 131 and the second input terminal 132 of the second input layer 12, and a low level voltage is provided to the third input terminal 133 and the fourth input terminal 134 of the second input layer 12. Thus the potentials of the connecting nodes 135 in each line of the connecting nodes 135 that extends along the X-axis direction are equivalent to each other. The potentials of the connecting nodes 135 in each line of the connecting nodes 135 that extend along the Y-axis direction progressively decrease from the connecting node 135 closest to the first and second input terminals 131, 132 to the connecting node 135 farthest from the first and second input terminals 131, 132. FIG. 7 is an abbreviated, equivalent circuit diagram of part of the mesh circuit 13 during the first period “t₁”. The resistors R₁ and R₂ are two equivalent resistors along the Y-axis direction, respectively at two opposite sides of the connecting node 135a. Thus, the output terminal 111 that is interconnected to the connecting node 135a provides a Y-axis voltage U_{Y}. According to the below formula (1), a Y-coordinate position d_{Y} of the touch point 112 on the first input layer 11 can be calculated as follows:
d_{Y}=U_{Y}*D_{Y}/(U_{H}−U_{L}) (1)
D_{Y} is a width of the first input layer 11 along the Y-axis direction, and is equal to a distance between the first electrical node 141 and the fourth electrical node 144. U_{H} is equal to the high level voltage provided to the first input terminal 131 and the second input terminal 132. U_{L} is equal to the low level voltage provided to the third input terminal 133 and the fourth input terminal 134.

In the second period “t₂”, a high level voltage is provided to the first input terminal 131 and the fourth input terminal 134 of the second input layer 12, and a low level voltage is provided to the second input terminal 132 and the third input terminal 133 of the second input layer 12. Thus the potentials of the connecting nodes 135 in each line of the connecting nodes 135 that extend along the Y-axis direction are equivalent to each other. The potentials of the connecting nodes 135 in each line of the connecting nodes 135 that extend along the X-axis direction progressively increase from the connecting node 135 closest to the first and fourth input terminals 131, 134 to the connecting node 135 farthest from the first and fourth input terminals 131, 134. FIG. 8 is an abbreviated, equivalent circuit diagram of the mesh circuit 13 during the second period “t₂”. The resistors R₃ and R₄ are two equivalent resistors along the X-axis direction, respectively at two opposite sides of the connecting node 135a. Thus, the output terminal 111 that is interconnected to the connecting node 135a provides an X-axis voltage Uₓ. According to the below formula (2), an X-coordinate position dₓ of the touch point 112 on the first input layer 11 can be calculated as follows:
dₓ=Uₓ*Dₓ/(U_{H}-U_{L}) (2)
Dₓ is a width of the second input layer 12 along the X-axis direction, and is equal to a distance between the first electrical node 141 and the second electrical node 142. U_{H} is equal to the high level voltage provided to the first input terminal 131 and the fourth input terminal 134. U_{L} is equal to the low level voltage provided to the second input terminal 132 and the third input terminal 133.

The touch panel 1 needs four connecting lines (not shown) for respectively providing the voltages to the four input terminals 131, 132, 133, 134. Thus the layout of the touch panel 1 is rather complicated, and the method of driving the touch panel 1 is relatively complicated.

What is needed, therefore, is a touch panel that can overcome the above-described problems.

### SUMMARY

In one preferred embodiment, a touch panel includes a first input layer having an output terminal, and a second input layer parallel to the first input layer. The second input layer includes a first electrical set, a second electrical set, a mesh circuit, and a switch circuit. The first electrical set includes a first electrical node, a second electrical node, a third electrical node, and a fourth electrical node, the first, second, third, and fourth electrical nodes respectively located at four vertexes of an imaginary rectangle on the second input layer. The mesh circuit having a plurality of resistors connected between the four electrical nodes. The second electrical set includes a first input terminal and a second input terminal. The switch circuit electrically connected between the first electrical set and the second electrical set.

Other novel features and advantages will become more apparent from the following detailed description when taken in conjunction with the accompanying drawings. In the drawings, all the views are schematic.

### BRIEF DESCRIPTION OF THE DRAWINGS

FIG. 1 is an exploded, abbreviated, isometric view of a touch panel according to an exemplary embodiment of the present invention, the touch panel including a mesh circuit and defining X-Y Cartesian axes.

FIG. 2 is a waveform diagram of voltages applied to each of two input terminals of the touch panel of FIG. 1 over two successive periods of time, whereby a position of a user's touch on the touch panel can be determined.

FIG. 3 is an abbreviated, equivalent circuit diagram of part of the mesh circuit of FIG. 1 during a first one of the time periods of FIG. 2, showing electrical relationships along the Y-axis direction.

FIG. 4 is an abbreviated, equivalent circuit diagram of part of the mesh circuit of FIG. 1 during a second one of the time periods of FIG. 2, showing electrical relationships along the X-axis direction.

FIG. 5 is an exploded, abbreviated, isometric view a conventional touch panel, the touch panel including a mesh circuit and defining X-Y Cartesian axes.

FIG. 6 is a waveform diagram of voltages applied to each of four input terminals of the touch panel of FIG. 5 over two successive periods of time, whereby a position of a user's touch on the touch panel can be determined.

FIG. 7 is an abbreviated, equivalent circuit diagram of part of the mesh circuit of FIG. 5 during a first one of the time periods of FIG. 6, showing electrical relationships along the Y-axis direction.

FIG. 8 is an abbreviated, equivalent circuit diagram of part of the mesh circuit of FIG. 5 during a second one of the time periods of FIG. 6, showing electrical relationships along the X-axis direction.

### DETAILED DESCRIPTION OF PREFERRED EMBODIMENTS

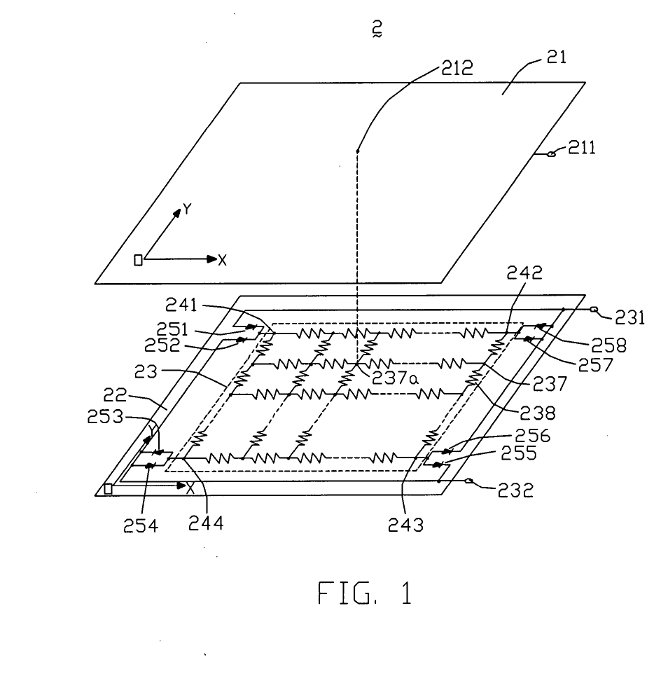

FIG. 1 is a schematic, exploded, abbreviated, isometric view of a touch panel according to an exemplary embodiment of the present invention. The touch panel 2 includes a first input layer 21, and a second input layer 22 that is parallel to the first input layer 21. The first input layer 21 and the second input layer 22 are spaced apart from each other.

The first input layer 21 includes an output terminal 211. The second input layer 22 includes a first electrical node 241, a second electrical node 242, a third electrical node 243, and a fourth electrical node 244, which are respectively located at four vertexes of an imaginary square defined on the second input layer 22. The second input layer 22 also includes a switch circuit (not labeled), and a mesh circuit 23 which is connected with the four electrical nodes 241, 242, 243, 244.

The mesh circuit 23 includes a plurality of connecting nodes 237 (only one labeled) and a plurality of resistors 238 (only one labeled). In general, each resistor 238 is connected between two corresponding adjacent connecting nodes 237. However, certain of the resistors 238 are connected between a respective one of the first, second, third, and fourth electrical nodes 241, 242, 243, 244 and a corresponding adjacent connecting node 237. Resistances of the resistors 238 are equal to each other. Distances between two adjacent connecting nodes 237 (and between any one of the first, second, third, and fourth electrical nodes 241, 242, 243, 244 and the corresponding adjacent connecting node 237) are equal to each other.

The switch circuit includes a first input terminal 231, a second input terminal 232, a first diode 251, a second diode 252, a third diode 253, a fourth diode 254, a fifth diode 255, a sixth diode 256, a seventh diode 257, and an eighth diode 258.

The first diode 251 is connected between the first input terminal 231 and the first electrical node 241. The positive terminal of the first diode 251 is connected to the first input terminal 231.

The second diode 252 is connected between the second input terminal 232 and the first electrical node 241. The positive terminal of the second diode 252 is connected to the second input terminal 232.

The third diode 253 and the fourth diode 254 are connected in parallel between the second input terminal 232 and the fourth electrical node 244. The positive terminal of the third diode 253 and the negative terminal of the fourth diode 254 are connected to the fourth electrical node 244.

The fifth diode 255 is connected between the second input terminal 232 and the third electrical node 243. The negative terminal of the fifth diode 255 is connected to the second input terminal 232.

The sixth diode 256 is connected between the first input terminal 231 and the third electrical node 243. The negative terminal of the sixth diode 256 is connected to the first input terminal 231.

The seventh diode 257 and the eighth diode 258 are connected in parallel between the first input terminal 231 and the second electrical node 242. The positive terminal of the seventh diode 257 and the negative terminal of the eighth diode 258 are connected to the second electrical node 242.

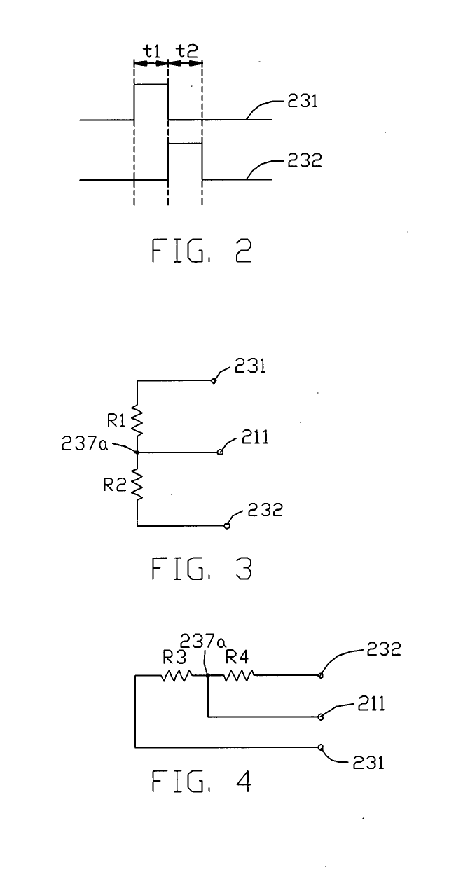

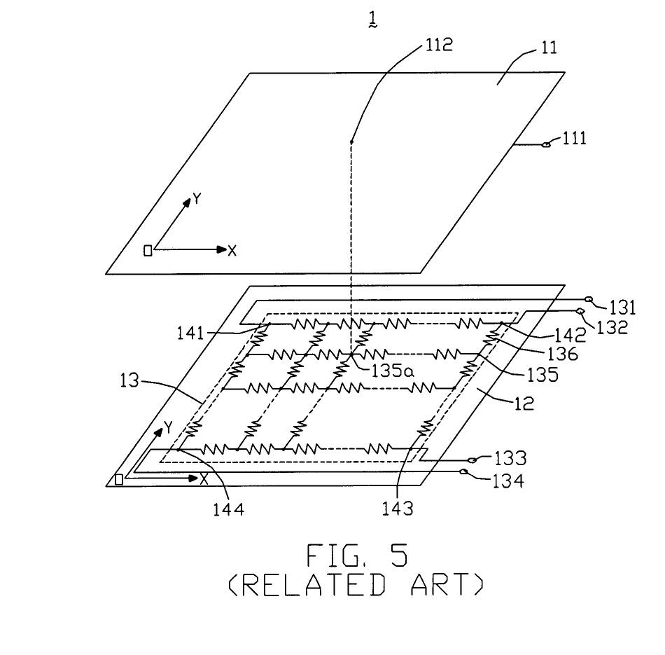

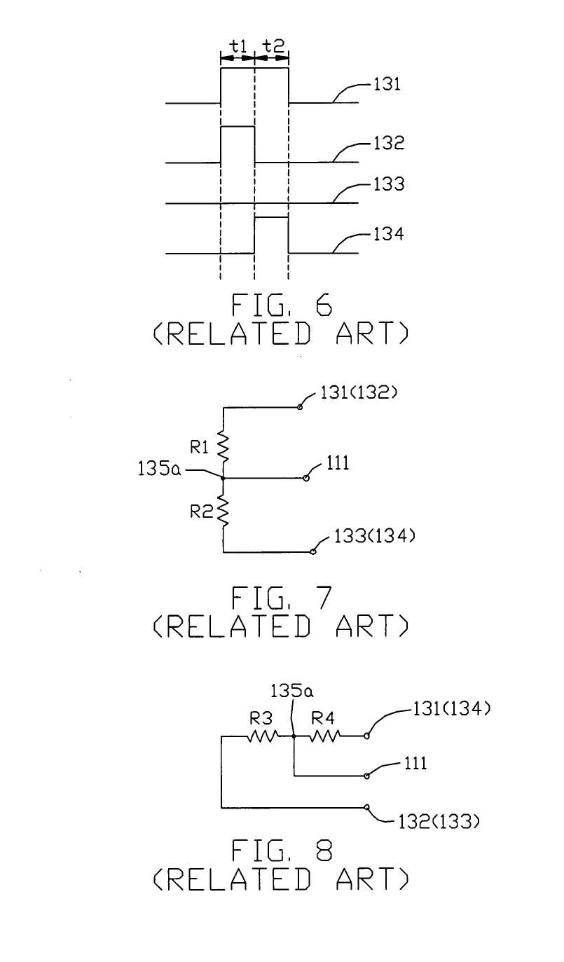

In order to conveniently describe operation of the touch panel 2, each of the first input layer 21 and the second input layer 22 is defined to include Cartesian axes (i.e. an X-axis and a Y-axis). Referring also to FIGS. 2, 3 and 4, the operation of the touch panel 2 is generally as follows.

When a user's finger (or a stylus) touches the first input layer 21, a touch point 212 of the first input layer 11 is electrically connected to a corresponding connecting node 237a of the mesh circuit 23 of the second input layer 22. A period of time during which the touch point 212 is connected to the corresponding connecting node 237a is divided into a first period “t₁” and a second period “t₂”. The first period “t₁” can be a first half of said period of time. The second period “t₂” can be a second half of said period of time.

In the first period “t₁”, a high level voltage is provided to the first input terminal 231 of the second input layer 22, and a low level voltage is provided to the second input terminal 232 of the second input layer 22. Thus the first diode 251, the third diode 253, the fifth diode 255, and the eighth diode 258 are turned on, and the second diode 252, the fourth diode 254, the sixth diode 256, and the seventh diode 257 are turned off. The potentials of the connecting nodes 237 in each line of the connecting nodes 237 that extends along the X-axis direction are equivalent to each other. The potentials of the connecting nodes 237 in each line of the connecting nodes 237 that extend along the Y-axis direction progressively decrease from the connecting node 237 closest to the first terminal 231 to the connecting node 237 farthest from the first terminal 231. Thus, a current flows from the first and second electrical nodes 241, 242 to the fourth and third electrical nodes 244, 243. FIG. 3 is an abbreviated, equivalent circuit diagram of part of the mesh circuit 23 during the first period “t₁”. The two resistors R₁ and R₂ are equivalent resistors along the Y-axis direction respectively at two opposite sides of the connecting node 237a. Thus, the output terminal 211 that is interconnected to the connecting node 237a provides a Y-axis voltage U_{Y}. According to the below formula (3), a Y-coordinate position of the touch point 212 on the first input layer 21 can be calculated as follows:
d_{Y}=U_{Y}*D_{Y}/(U_{H}−U_{L}) (3)
D_{Y} is a width of the first input layer 21 in the Y-axis direction, and is equal to a distance between the first electrical node 241 and the fourth electrical node 244. U_{H} is equal to the high level voltage provided to the first input terminal 231. U_{L} is equal to the low level voltage provided to the second input terminal 232.

In the second period “t₂”, a high level voltage is provided to the second input terminal 232, and a low level voltage is provided to the first input terminal 231. Thus the first diode 251, the third diode 253, the fifth diode 255, and the eighth diode 258 are turned off, and the second diode 252, the fourth diode 254, the sixth diode 256, and the seventh diode 257 are turned on. The potentials of the connecting nodes 237 in each line of the connecting nodes 237 that extend along the Y-axis direction are equivalent to each other. The potentials of the connecting nodes 237 in each line of the connecting nodes 237 that extend along the X-axis direction progressively increase from the connecting node 237 closest to the first and second terminals 231, 232 to the connecting node 237 farthest from the first and second terminals 231, 232. Thus, a current flows from the first and fourth electrical nodes 241, 244 to the second and third electrical nodes 242, 243. FIG. 4 is an abbreviated, equivalent circuit diagram of part of the mesh circuit 23 during the second period “t₂”. The two resistors R₃ and R₄ are equivalent resistors along the X-axis direction respectively at two opposite sides of the connecting node 237a. Thus, the output terminal 211 that is interconnected to the connecting node 237a provides an X-axis voltage Uₓ. According to the below formula (4), an X-coordinate position of the touch point 212 on the first input layer 21 can be calculated as follows:
d_{X}=U_{X}*D_{X}/(U_{H}−U_{L}) (4)
D_{X} is a width of the first input layer 21 in the X-axis direction, and is equal to a distance between the first electrical node 241 and the second electrical node 242. U_{H} is equal to the high level voltage provided to the second input terminal 232. U_{L} is equal to the low level voltage provided to the first input terminal 231.

Because both the X-coordinate and the Y-coordinate of the touch point 212 on the first touch layer 21 can be calculated, the position of the touch point 212 on the first touch layer 21 is confirmed. Electronic signals generated by the touch panel 2 according to a confirmed position of the touch point 212 can also be provided to an external device (not shown) for controlling an LCD covered by the touch panel 2. Thus, a predetermined function of the external device can be performed according to the electronic signals.

The touch panel 2 needs only two connecting lines (not shown) for providing the voltages to the two input terminal 231, 232 respectively. Thus the layout of the touch panel 2 is relatively simple, and the method of driving the touch panel 2 is also relatively simple.

In an alternative embodiment, the diodes 251, 252, 253, 254, 255, 256, 257, 258 of the switch circuit (not labeled) can instead be transistors. In such case, the transistors function as switch units similarly to the diodes 251, 252, 253, 254, 255, 256, 257, 258. In alternative operation, the first period “t₁” can be less than half of the period of time during which the touch point 212 is connected to the corresponding connecting node 237a, and the second period “t₂” can be more than half of said period of time. In other alternative operation, the first period “t₁” can be more than half of said period of time, and the second period “t₂” can be less than half of said period of time. A touch LCD, which includes an LCD panel and the touch panel 2 covering a surface of the LCD panel, can also be provided.

It is to be further understood that even though numerous characteristics and advantages of the present embodiments have been set out in the foregoing description, together with details of the structures and functions of the embodiments, the disclosure is illustrative only, and changes may be made in detail, especially in matters of size and arrangement of parts within the principles of the invention to the full extent indicated by the broad general meaning of the terms during which the appended claims are expressed.

What is claimed is:

1. A touch panel comprising:
a first input layer comprising an output terminal; and
a second input layer parallel to the first input layer, the second input layer comprising:
a first electrical set comprising a first electrical node, a second electrical node, a third electrical node, and a fourth electrical node, the first, second, third, and fourth electrical nodes respectively located at four vertexes of an imaginary rectangle on the second input layer;
a mesh circuit connected with the four electrical nodes, the mesh circuit comprising a plurality of resistors;
a second electrical set comprising a first input terminal and a second input terminal; and
a switch circuit electrically connected between the first electrical set and the second electrical set.

2. The touch panel as claimed in claim 1, wherein when a touch point of the first input layer is electrically connected to a corresponding connecting node of the mesh circuit of the second input layer in a touching process, and two different voltages are respectively provided to the first input terminal and the second input terminal, in a first time division of a period of the touching process, the potentials of the first electrical node and the second electrical node are equal to each other, the potentials of the third electrical node and the fourth electrical node are equal to each other, and the potential of the first electrical node is different from that of the fourth electrical node, and in a second time division of said period of the touching process, the potentials of the first electrical node and the fourth electrical node are equal to each other, the potentials of the second electrical node and the third electrical node are equal to each other, the potential of the first electrical node is different from that of the second electrical node.

3. The touch panel as claimed in claim 1, wherein when a touch point of the first input layer is electrically connected to a corresponding connecting node of the mesh circuit of the second input layer in a touching process, and two different voltages are respectively provided to the first input terminal and the second input terminal, a current flows from the first and second electrical nodes to the fourth and third electrical nodes in a first time division of a period of the touching process, and a current flows from the first and fourth electrical nodes to the second and third electrical nodes in a second time division of said period of the touching process.

4. The touch panel as claimed in claim 3, wherein the first time division of said period of the touching process is equal to half said period of the touching process, and the second time division of said period of the touching process is equal to half said period of the touching process.

5. The touch panel as claimed in claim 3, wherein the first time division of said period of the touching process is less than or greater than half said period of the touching process, and the second time division of said period of the touching process is correspondingly greater than or less than half said period of the touching process.

6. The touch panel as claimed in claim 1, wherein the switch circuit comprises:
a first switch unit, a second switch unit, a third switch unit, a fourth switch unit, a fifth switch unit, a sixth switch unit, a seventh switch unit, and an eighth switch unit;
wherein the first electrical node is connected to the first and second input terminals, respectively via the first and second switch units;
the second electrical node is connected to the first input terminal respectively via the seventh and eighth switch units;
the third electrical node is connected to the first and second input terminals, respectively via the sixth and fifth switch units; and
the fourth electrical node is connected to the second input terminal respectively via the third and the fourth switch units.

7. The touch panel as claimed in claim 6, wherein the second, fourth, sixth and seventh switch units are turned on when the first, third, fifth, and eighth switch units are turned off, and the second, fourth, sixth and seventh switch units are turned off when the first, third, fifth, and eighth switch units are turned on.

8. The touch panel as claimed in claim 7, wherein the switch units are diodes.

9. The touch panel as claimed in claim 8, wherein the positive terminals of the first diode and the eighth diode and the negative terminals of the sixth diode and the seventh diode are connected to the first input terminal, and the positive terminals of the second diode and the fourth diode and the negative terminals of the third diode and the fifth diode are connected to the second input terminal.

10. The touch panel as claimed in claim 7, wherein the switch units are transistors.

11. The touch panel as claimed in claim 1, wherein resistances of the resistors are equal to each other.

12. A touch liquid crystal display (LCD) comprising:
a liquid crystal display panel; and
a touch panel covering the liquid crystal display panel, the touch panel comprising:
a first input layer comprising an output terminal; and
a second input layer parallel to the first input layer, the second input layer comprising:
a first electrical set comprising a first electrical node, a second electrical node, a third electrical node, and a fourth electrical node, the first, second, third, and fourth electrical nodes respectively located at four vertexes of an imaginary rectangle on the second input layer;
a mesh circuit connected with the four electrical nodes, the mesh circuit comprising a plurality of resistors;
a second electrical set comprising a first input terminal and a second input terminal; and
a switch circuit electrically connected between the first electrical set and the second electrical set.

13. The touch LCD as claimed in claim 12, wherein when a touch point of the first input layer is electrically connected to a corresponding connecting node of the mesh circuit of the second input layer in a touching process, providing two different voltages respectively to the first input terminal and the second input terminal; in a preceding half time of touching process, the potentials of the first electrical node and the second electrical node are equal to each other, the potentials of the third electrical node and the fourth electrical node are equal to each other, the potential of the first electrical node is different from that of the fourth electrical node; and in a rear half time of the touching process, the potentials of the first electrical node and the fourth electrical node are equal to each other, the potentials of the second electrical node and the third electrical node are equal to each other, the potential of the first electrical node is different from that of the second electrical node.

14. The touch LCD as claimed in claim 12, wherein when a touch point of the first input layer is electrically connected to a corresponding connecting node of the mesh circuit of the second input layer in a touching process, providing two different voltages respectively to the first input terminal and the second input terminal; a current flows from the first and the second electrical nodes to the third and fourth electrical nodes in a preceding half time of touching process; and a current flows from the first and fourth electrical nodes to the second and third electrical nodes in a rear half time of the touching process.

15. The touch LCD as claimed in claim 12, wherein the switch circuit comprises:
a first switch unit, a second switch unit, a third switch unit, a fourth switch unit, a fifth switch unit, a sixth switch unit, a seventh switch unit, and a eighth switch unit;
wherein the first electrical node is respectively connected to the first and second input terminals, respectively via the first and second switch units;
the second electrical node is connected to the first input terminal respectively via the seventh and eighth switch units;
the third electrical node respectively connected to the first and second input terminals, respectively via the sixth and fifth switch units; and
the fourth electrical node connected to the second input terminal respectively via the third and the fourth switch units.

16. The touch LCD as claimed in claim 15, wherein the second, fourth, sixth and seventh switch units are turned on when the first, third, fifth, and eighth switch units are turned off; the second, fourth, sixth and seventh switch units are turned off when the first, third, fifth, and eighth switch units are turned on.

17. The touch LCD as claimed in claim 16, wherein the switch units are diodes.

18. The touch LCD as claimed in claim 17, wherein the positive terminals of the first diode and the eighth diode, the negative terminals of the sixth diode and the seventh diode are connected to the first input terminal, the positive terminals of the second diode and fourth diode and the negative terminals of the third diode and the fifth diode are connected to the second input terminal.

19. The touch LCD as claimed in claim 18, wherein the switch units are transistors.
